(19) United States
(12) Patent Application Publication
(10) Pub. No.: US 2021/0107094 A1
(43) Pub. Date: Apr. 15, 2021

(54) APPARATUS FOR AND METHOD OF POLISHING SURFACE OF SUBSTRATE

(71) Applicant: HAESUNG DS CO., LTD., Changwon-si (KR)

(72) Inventors: Sung Il KANG, Gimhae-si (KR); Se Chuel PARK, Changwon-si (KR); Jong Hoe KU, Gimhae-si (KR); In Seob BAE, Changwon-si (KR)

(21) Appl. No.: 16/846,953

(22) Filed: Apr. 13, 2020

(30) Foreign Application Priority Data
Oct. 14, 2019 (KR) 10-2019-0127167

(51) Int. Cl. B23K 26/352; H01L 21/3105; B23K 26/0622

(52) U.S. Cl. CPC B23K 26/3576; B23K 2101/40; B23K 26/0624; H01L 21/31058

(57) ABSTRACT

According to one or more embodiments, there is provided an apparatus for polishing a surface of a substrate to remove a resin layer formed on the surface of the substrate having a groove, the apparatus including: a laser irradiation apparatus configured to irradiate a laser to the resin layer to remove at least a portion of a resin from the resin layer except for a portion of the resin layer arranged in the groove.

### CROSS-REFERENCE TO RELATED APPLICATION

This application claims the benefit of Korean Patent Application No. 10-2019-0127167, filed on Oct. 14, 2019, in the Korean Intellectual Property Office, the disclosure of which is incorporated herein in its entirety by reference.

### BACKGROUND

### 1. Field

One or more embodiments relate to an apparatus for and method of polishing a surface of a substrate.

### 2. Description of Related Art

With the development of the electronic industry, the demand for miniaturization and multifunctionalization of electronic components has gradually increased. Also, substrates on which electronic components are mounted are also formed in various structures and shapes.

Substrates are manufactured to have various structures such as a circuit pattern and an insulating layer. In order to manufacture such substrates, a process of removing an unnecessary layer or material by polishing a surface of a substrate may be necessary.

Korean Patent Publication No. 2011-0053753 discloses an apparatus for polishing a substrate, the apparatus having a chemical polishing portion filled with an etchant and a mechanical polishing portion including a brush.

### SUMMARY

One or more embodiments include an apparatus for and method of polishing the surface of a substrate.

Additional aspects will be set forth in part in the description which follows and, in part, will be apparent from the description, or may be learned by practice of the presented embodiments of the disclosure.

According to one or more embodiments, there is provided an apparatus for polishing a surface of a substrate to remove a resin layer formed on a surface of a substrate having a groove, the apparatus including: a laser irradiation apparatus configured to irradiate a laser to the resin layer to remove at least a portion of a resin from the resin layer except for a portion of the resin layer arranged in the groove.

The resin layer may include an epoxy resin or a polyimide resin.

The laser irradiation apparatus may irradiate at least one of a pulse wave laser and a continuous wave laser.

The wavelength range of the laser irradiated by the laser irradiation apparatus may be from 355 nm to 1064 nm.

The laser irradiation apparatus may include a plurality of laser irradiation apparatuses.

According to one or more embodiments, there is provided a method of polishing a surface of a substrate includes: forming a groove in at least one surface of the substrate, forming a resin layer on the at least one surface of the substrate in which the groove is formed, and irradiating a laser to the resin layer to remove at least a portion of a resin from the resin layer except for a portion of the resin layer arranged in the groove.

The resin layer may include an epoxy resin or a polyimide resin.

The laser may be irradiated by at least one laser irradiation apparatus.

The laser may include at least one of a pulse wave laser and a continuous wave laser.

The wavelength range of the laser may be from 355 nm to 1064 nm.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic diagram illustrating process steps of polishing a surface of a substrate by using an apparatus for polishing a surface of a substrate, according to an embodiment;

FIG. 2 is a schematic cross-sectional view showing the state of the substrate at point I of FIG. 1;

FIG. 3 is a schematic cross-sectional view showing the state of the substrate at point II of FIG. 1;

FIG. 4 is a schematic cross-sectional view showing the state of the substrate at point III of FIG. 1;

FIG. 5 is a schematic diagram illustrating process steps of polishing a surface of a substrate by using an apparatus for polishing a surface of a substrate, according to another embodiment; and

FIG. 6 is a schematic diagram illustrating process steps of polishing a surface of a substrate, according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

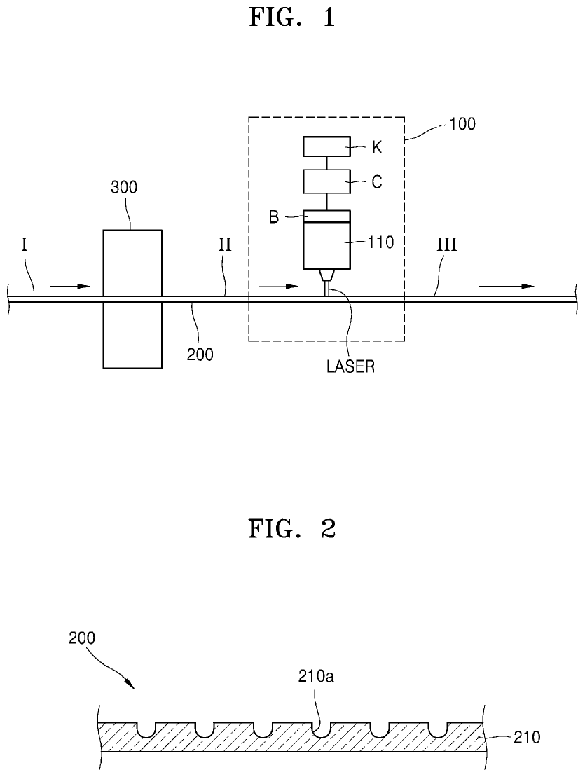

FIG. 1 is a schematic diagram illustrating process steps of polishing a surface of a substrate by using an apparatus 100 (hereinafter, referred to as a substrate surface polishing apparatus) for polishing a surface of a substrate, according to an embodiment.

As shown in FIG. 1, the substrate surface polishing apparatus 100 according to the embodiment is used for polishing a surface of a substrate 200 while transferring the substrate 200 by a roll-to-roll process. The substrate surface polishing apparatus 100 according to the embodiment corresponds to one of apparatuses for performing a process of manufacturing a semiconductor package and a substrate for a lead frame.

Although the substrate surface polishing apparatus 100 according to the present embodiment is an apparatus for polishing the surface of the substrate 200 while transferring the substrate 200 by a roll-to-roll process, the disclosure is not limited thereto. That is, when the substrate 200 has the shape of a panel, the substrate surface polishing apparatus 100 according to the present embodiment may also polish the surface of the substrate 200 while transferring the substrate 200 by using a conveyor transfer method or the like.

The substrate surface polishing apparatus 100 receives the substrate 200 from a resin layer forming unit 300, which is a device for performing the immediately preceding process, and performs a function of polishing the surface of the substrate 200.

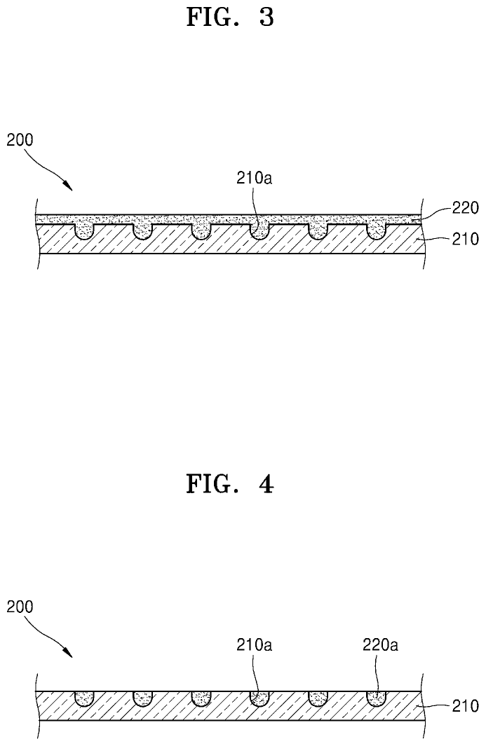

The shape of the substrate 200 emerging from the resin layer forming unit 300 is illustrated in FIG. 3. The substrate 200 includes a raw material 210 and a resin layer 220 formed on the upper surface of the raw material 210. Details are described below.

The substrate surface polishing apparatus 100 includes a laser irradiation apparatus 110.

The laser irradiation apparatus 110 irradiates a laser to a surface of the substrate 200 to polish the surface. In this case, the surface of the substrate 200 to which the laser is irradiated denotes a portion of the substrate 200 to which the laser is irradiated by the laser irradiation apparatus 110. That is, the surface of the substrate 200 may be a surface of the resin layer 220 at the beginning of the polishing process, and may be an exposed surface of the raw material 210 at the end of the polishing process since the resin layer 220 is gradually polished and removed.

The laser irradiation apparatus 110 irradiates a laser and has a function of automatically recognizing a distance from the substrate 200 and keeping a focal length of a laser dot constant, like a general laser irradiator.

The laser irradiated by the laser irradiation apparatus 110 may be any kind of laser as long as the laser may be irradiated to the resin layer 220 and the resin layer 220 may be removed by reaction. For example, the laser irradiation apparatus 110 may irradiate a single laser or a combination of lasers such as pulse wave lasers and continuous wave lasers, and the wavelength range of the laser irradiated by the laser irradiation apparatus 110 may be from 355 nm which is the wavelength of ultraviolet (UV) laser, to 1064 nm which is the wavelength of infrared (IR) laser.

In addition, the laser irradiation apparatus 110 is configured to be able to freely change various conditions, such as output, irradiation direction, and irradiation movement. To this end, the laser irradiation apparatus 110 may include a movement driver B, a controller C, an input unit K, and the like.

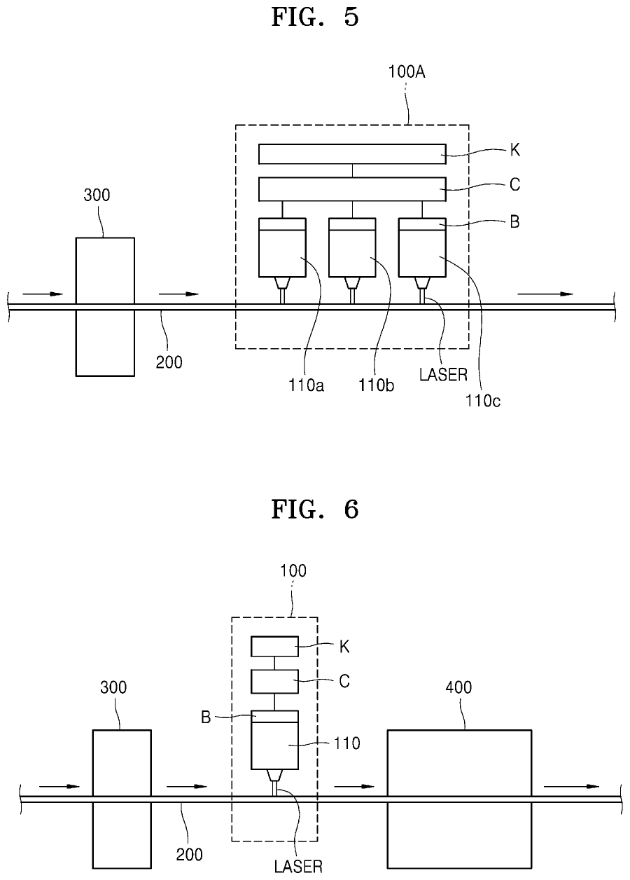

In FIG. 1, one laser irradiation apparatus 110 is used, but the disclosure is not limited thereto. That is, according to an embodiment, a plurality of laser irradiation apparatuses may be provided. One such example is a substrate surface polishing apparatus 100A shown in FIG. 5. In FIG. 5, a structure in which the substrate surface polishing apparatus 100A includes a plurality of laser irradiation apparatuses 110a, 110b, and 110c is shown.

In addition, according to the present embodiment, the resin layer 220 is formed on one surface of the substrate 200 and the substrate surface polishing apparatus 100 has a structure for removing only the resin layer 220 on one surface of the substrate 200. However, the disclosure is not limited thereto. That is, according to the present embodiment, the resin layer 220 may be formed on both surfaces of the substrate 200 and the substrate surface polishing apparatus 100 may have at least one device for removing the resin layer 220 on both surfaces or one surface of the substrate 200. Accordingly, the number and position of laser irradiation apparatuses may be appropriately modified.

Hereinafter, with reference to FIGS. 1 to 4, a process of polishing a surface of a substrate by using the substrate surface polishing apparatus 100 described above is described.

FIG. 2 is a schematic cross-sectional view showing the state of the substrate 200 at the point I of FIG. 1, and FIG. 3 is a schematic cross-sectional view showing the state of the substrate 200 at the point II of FIG. 1. FIG. 4 is a schematic cross-sectional view showing the state of the substrate 200 at the point III of FIG. 1.

First, the state of the substrate 200 before entering into the resin layer forming unit 300 is described.

FIG. 2 shows a cross-sectional view of the substrate 200 at the point I before the substrate 200 enters the resin layer forming unit 300. Grooves 210a are formed in the raw material 210 of the substrate 200 through an etching process of a previous step. In this case, the raw material 210 of the substrate 200 includes a copper material, but the disclosure is not limited thereto. That is, the raw material 210 of the substrate 200 may include, in addition to copper, various types of metals, plastics, and the like used in lead frames and semiconductor packages.

Next, the substrate 200 enters the resin layer forming unit 300.

In the resin layer forming unit 300, the resin layer 220 is formed on a surface, in which the grooves 210a are formed, among surfaces of the raw material 210 of the substrate 200. As a resin material constituting the resin layer 220, various polymer materials such as epoxy resin and polyimide resin, or a composite material including a polymer material, a ceramic filler, and the like may be used. A material that may be removed in response to a certain wavelength range of the laser irradiated by the laser irradiation apparatus 110 may be used as the resin material.

Subsequently, the substrate 200 enters the substrate surface polishing apparatus 100.

A user or the controller C controls the laser irradiation apparatus 110 to irradiate a laser to a surface, on which the resin layer 220 is formed, among surfaces of the substrate 200.

When the laser is irradiated to the resin layer 220, the resin layer 220 reacts with the laser and begins to be removed as the resin of the resin layer 220 is vaporized. The resin layer 220 is removed by a predetermined depth. To this end, the user or the controller C may use various methods such as adjusting the output amount of irradiated laser, appropriately setting the pitch between laser dots, and controlling a laser movement speed. In this case, since the wavelength of the irradiated laser has little reaction with the raw material 210 of the substrate 220, damage of the raw material 210 hardly progresses.

FIG. 4 shows a cross-sectional view of the substrate 200 at the point III, i.e., at a point where the substrate 200 has been polished by the substrate surface polishing apparatus 100. In the substrate 200, the remaining resin layer 220 except for a resin 220a arranged in the groove 210a are removed.

In the present embodiment, although, in the substrate 200 that has been polished by the substrate surface polishing apparatus 100, the remaining resin layer 220 except for the resin 220a arranged in the groove 210a has been removed, the disclosure is not limited thereto. That is, according to another embodiment, the polishing process may be performed by controlling the output and the direction of the laser so that a portion of the resin layer 220 around the groove 210a remains(first process), and in this case, an additional polishing process (second process) may be required. One such example is the example shown in FIG. 6. FIG. 6 shows a process of removing a residual resin by polishing, in an additional friction type polishing apparatus 400, the substrate 200 passing through the substrate surface polishing apparatus 100. In this case, a conventional friction type polishing apparatus may be used as the additional friction type polishing apparatus 400.

As described above, in the substrate surface polishing apparatus 100 and the polishing method according to the embodiment, the resin layer 220 of the substrate 200 is removed using a laser, and thus, a load is not directly applied to the substrate 200 for polishing. Therefore, the warpage or damage of the substrate 200 does not occur during the polishing process.

In addition, the substrate surface polishing apparatus 100 and the polishing method according to the embodiment may freely change the output and conditions of a laser to be irradiated. Therefore, the user may easily remove the resin layer 220 to a desired level, and thus, a precise polishing may be implemented.

Since a substrate surface polishing apparatus and method according to one or more embodiments remove a resin layer of a substrate by using a laser, the warpage and damage of the substrate can be prevented without applying a load to the substrate for polishing.

In addition, since the substrate surface polishing apparatus and method according to one or more embodiments may freely change the output and conditions of a laser to be irradiated, the resin layer can be easily removed to a desired level.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An apparatus for polishing a surface of a substrate to remove a resin layer formed on the surface of the substrate having a groove, the apparatus comprising:
a laser irradiation apparatus configured to irradiate a laser to the resin layer to remove at least a portion of a resin from the resin layer except for a portion of the resin layer arranged in the groove.

2. The apparatus of claim 1, wherein the resin layer comprises an epoxy resin or a polyimide resin.

3. The apparatus of claim 1, wherein the laser irradiation apparatus is configured to irradiate at least one of a pulse wave laser and a continuous wave laser.

4. The apparatus of claim 1, wherein a wavelength range of the laser irradiated by the laser irradiation apparatus is from 355 nm to 1064 nm.

5. The apparatus of claim 1, wherein the laser irradiation apparatus comprises a plurality of laser irradiation apparatuses.

6. A method of polishing a surface of a substrate, the method comprising:
forming a groove in at least one surface of the substrate;
forming a resin layer on the at least one surface of the substrate in which the groove is formed; and
irradiating a laser to the resin layer to remove at least a portion of a resin from the resin layer except for a portion of the resin layer arranged in the groove.

7. The method of claim 6, wherein the resin layer comprises an epoxy resin or a polyimide resin.

8. The method of claim 6, wherein the laser is irradiated by at least one laser irradiation apparatus.

9. The method of claim 6, wherein the laser comprises at least one of a pulse wave laser and a continuous wave laser.

10. The method of claim 6, wherein a wavelength range of the laser is from 355 nm to 1064 nm.
